(19) United States
(12) Patent Application Publication
(10) Pub. No.: US 2007/0291574 A1
(43) Pub. Date: Dec. 20, 2007

(54) METHOD FOR MANUFACTURING ELECTRO-OPTICAL DEVICE AND ELECTRO-OPTICAL DEVICE

(75) Inventor: Yoichi Noda, Fujimi-machi (JP)

Correspondence Address: WORKMAN NYDEGGER, 60 EAST SOUTH TEMPLE, 1000 EAGLE GATE TOWER, SALT LAKE CITY, UT, 84111, US

(73) Assignee: SEIKO EPSON CORPORATION, Tokyo (JP)

(21) Appl. No.: 11/758,549

(22) Filed: Jun. 5, 2007

(30) Foreign Application Priority Data
Jun. 8, 2006 (JP) 2006-159377

(51) Int. Cl. G11C 8/00

(52) U.S. Cl. 365/230.05

(57) ABSTRACT

A method for manufacturing an electro-optical device which has first and second electrodes, an electro-optical layer interposed between the first and second electrodes and a plurality of pixel regions arranged in a plane, and performs display by transmitting light through each of colored layers provided correspondingly to each of the pixel regions. The method includes (a) forming a first partition wall partitioning the pixel regions on a first substrate and (b) forming first electrodes by applying first electrode forming material liquid to the individual areas partitioned by the first partition wall. In step (b) a layer thickness of each of the first electrodes is set depending on a wavelength range of light transmitted through the colored layer provided correspondingly thereto.

### BACKGROUND OF THE INVENTION

1. Technical Field

The present invention relates to a method for manufacturing an electro-optical device such as a liquid crystal apparatus and to an electro-optical device.

2. Related Art

There has been widely used a liquid crystal apparatus as a unit for displaying image information in electronic apparatuses such as a notebook computer, a mobile-phone and an electronic databook in the past. These liquid crystal apparatuses incorporate a color filter substrate (facing substrate) for color display. The color filter substrate includes colored layers of three colors red (R), green (G), and blue (B) arrayed on a base substrate made of a transparent glass or the like correspondingly to pixels with a predetermined pattern, for example. Formed on an upper surface of the colored layer are a transparent electrode for driving a liquid crystal layer and an orientation film for orienting liquid crystal molecules constituting the liquid crystal layer.

In such a color filter substrate, when light is incident on the transparent electrode, reflection occurs on an incident plane and an emitting plane of the transparent electrode. Then interference takes place between the incident light and reflection light reflected on the emitting and incident planes. Here, each of the colored layers of three colors has the transparent electrode formed on the upper surface thereof, and thicknesses of the transparent electrodes are the same. This means that light incident on the transparent electrode includes a red light component, a green light component and a blue light component whose transmittances are different from one another. Therefore, the luminance variation occurs depending on the color light component displayed.

There has been proposed a liquid crystal apparatus in which the layer thickness of the transparent electrode is varied according to the color light component displayed by the colored layer provided corresponding to the transparent electrode (refer to an example of related art listed below, for example).

In the liquid crystal apparatus according to the related art example, the layer thickness of the transparent electrode is set to such a value that transmitted light and the reflection light mutually interfere and are intensified in the layer. This adjustment of the layer thickness of the transparent electrode for every color displayed by the pixel enables suppressing the luminance variation due to a color light component displayed by each pixel.

JP-7-56180 is an example of related art.

However, the liquid crystal apparatus of the related art example has the following disadvantage left. Specifically, in the liquid crystal apparatus of related art, the transparent electrodes are formed which have the layer thicknesses different for every one of three colors by, for example, repeating deposition and etching of transparent electrode material. Therefore, the process of forming the transparent electrode disadvantageously is complicated as compared with the case where the layer thicknesses of the transparent electrodes are the same for every one of three colors. In these days, display may be performed by using four colors of cyan (C) as well as R, G and B described above in order to obtain higher color reproducibility. In this case, disadvantageously more complicated is the process of forming the transparent electrode which has the layer thickness different for every one of three colors.

### SUMMARY

An advantage of the present invention is to provide an electro-optical device and a method for manufacturing an electro-optical device in which easily can be formed the transparent electrodes having the layer thicknesses different for every one of three colors displayed.

According to a first aspect of the invention, a method for manufacturing an electro-optical device which has first and second electrodes; an electro-optical layer interposed between the first and second electrodes; a plurality of pixel regions arranged in a plane; a plurality of colored layers provided correspondingly to the pixel regions respectively; and a color filter layer having the colored layers, the method includes (a) forming a first partition wall partitioning a surface of a first substrate correspondingly to the pixels, and (b) forming first electrodes by applying first electrode forming material liquid to the individual areas partitioned by the first partition wall. In step (b) a layer thickness of each of the first electrodes is set depending on a color component of light transmitted through the colored layer provided correspondingly thereto.

According to a second aspect of the invention, an electro-optical device includes first and second electrodes, an electro-optical layer interposed between the first and second electrodes, a plurality of pixel regions arranged in a plane, a plurality of colored layers provided correspondingly to the pixel regions respectively, and a color filter layer having the colored layers. The device further includes partition wall formed on a substrate and partitioning a surface of the substrate. A layer thickness of each of the first electrodes is set depending on a wavelength range of light transmitted through the each of the colored layer provided correspondingly thereto.

In this case, the layer thickness of the first electrode may be adjusted easily by varying an amount of the first electrode forming material liquid applied in the area partitioned by the first partition wall. The first electrode may be formed easily which has the layer thickness different for every color displayed.

Specifically, the first electrodes are made as follows. The first partition wall is formed on the first substrate to partition the pixel regions, and then the first electrode forming material liquid is applied in the individual pixel regions, dried and precipitated to form the first electrodes. Here, since the layer thickness of the first electrode is set to a valued depending on a wavelength range of light transmitted through the colored layer provided correspondingly thereto, light loss may be suppressed in the first electrode with respect to light having the wavelength range of light transmitted through the colored layer. For example, in the first electrodes, consider light which is incident on the first electrode and has the wavelength range of light transmitted through the colored layer. Light travels in the first electrode from an incident plane of the first electrode to an emitting plane. This light is a transmitted light. Light is reflected on the emitting plane and the incident plane, and travels to the emitting plane. This light is reflection light. The thickness of the first electrode is set so that the transmitted light and the reflection light mutually intensify. Therefore, light loss may be reduced in the first electrode with respect to light having the wavelength range of light transmitted through the colored layer. By this way, the luminance variation for every pixel may be suppressed.

Accordingly the electro-optical device may be easily manufactured which has the luminance variation suppressed for every pixel by varying the applied amount of the first electrode forming material liquid to adjust the layer thickness of the first electrode.

In the method for manufacturing an electro-optical device of the first aspect of the invention, it is preferable that the first partition wall have conductive properties and electrical continuity be established between the first electrodes with the first partition wall therebetween.

In the electro-optical device of the second aspect of the invention, it is preferable that the partition wall have conductive properties and electrical continuity be established between the first electrodes with the partition wall therebetween.

In this case, electrical continuity is established between the first electrodes with the (first) partition wall therebetween so that the first electrodes may have the same electric potential and the voltage of the first electrodes can be readily controlled.

In the method for manufacturing an electro-optical device of the first aspect of the invention, in step (b) the first electrode forming material liquid preferably be applied by a liquid droplet discharging method.

In this case, the first electrode may be formed selectively by use of the liquid droplet discharging method. Therefore, the first electrode forming material liquid may be prevented from being wasted to reduce the cost.

In the method for manufacturing an electro-optical device of the first aspect of the invention, the method preferably further include, (c) forming a second partition wall partitioning a surface of a second substrate correspondingly to the pixel on the second substrate, and (d) forming second electrodes by applying second electrode forming material liquid to the individual areas partitioned by the second partition wall and drying. In step (d) a layer thickness of each of the second electrodes preferably be set depending on a color light component of the colored layer provided correspondingly thereto.

In this case, the layer thickness of the second electrode may be adjusted easily by varying an amount of the second electrode forming material liquid applied in the area partitioned by the second partition wall. Therefore, the electro-optical device may be easily manufactured which has the luminance variation more suppressed for every pixel.

In the method for manufacturing an electro-optical device of the first aspect of the invention, in step (d) the second electrode forming material liquid preferably be applied by a liquid droplet discharging method.

In this case similar to the above case, the second electrode may be formed selectively by use of the liquid droplet discharging method. Therefore, the second electrode forming material liquid may be prevented from being wasted to reduce the cost.

In the method for manufacturing an electro-optical device of the first aspect of the invention, the method preferably further include (e) forming a color filter layer including the colored layers in the individual areas partitioned by the first partition wall before step (b).

In this case, the colored layer, and the first electrode are laminated in this order on the first substrate, and the image display may be performed by applying the voltage to the electro-optical layer interposed between the outermost first electrodes and the second electrodes.

In the method for manufacturing an electro-optical device of the first aspect of the invention, step (e) preferably include (f) forming insulating layers each of which is adjacent to the colored layer. In step (f) a layer thickness of the insulating layer preferably be set depending on a wavelength range of light transmitted through the colored layer provided correspondingly thereto.

In this case, the colored layer is provided with the insulating layer adjacent thereto. Therefore, even if the layer thicknesses of the colored layers are different with each other, the entire thickness of the colored layer and insulating layer may be uniform for each of the pixel regions. Here, the layer thickness of the insulating layer may be set depending on the wavelength range of light transmitted through the corresponding colored layer to suppress luminance decrease and color drift for every pixel similar to the above.

In the method for manufacturing an electro-optical of the first aspect of the invention, it is preferable that the electro-optical layer constitute a liquid crystal layer, and the method further include (g) forming an orientation film on the first electrodes. In step (g) a layer thickness of the orientation film preferably be set depending on a wavelength range of light transmitted through the colored layer provided correspondingly thereto.

In this case, the thickness layer of the orientation film, which controls orientation of liquid crystal molecules of a liquid crystal layer constituting the liquid crystal apparatus, may be set depending on the wavelength range of light transmitted through the colored layers to further suppress the luminance variation for every pixel similar to the above.

### BRIEF DESCRIPTION OF THE DRAWINGS

The invention will be described with reference to the accompanying drawings, wherein like numbers reference like elements.

FIG. 1 is a plan view of a liquid crystal apparatus according to an embodiment of the invention.

FIG. 2 is a cross sectional view taken along line A-A in FIG. 1, looking in the direction of the appended arrows.

FIG. 3 is an enlarged partial view of FIG. 2.

FIG. 4 is an equivalent circuit schematic view of the liquid crystal apparatus of FIG. 1.

FIGS. 5A to 5E are cross sectional views showing a manufacturing step of the liquid crystal apparatus according to the embodiment.

FIGS. 6A to 6D are cross sectional views showing a manufacturing step of the liquid crystal apparatus.

FIG. 7 is a perspective view of a mobile-phone provided with the liquid crystal apparatus according to the embodiment.

### DESCRIPTION OF EXEMPLARY EMBODIMENTS

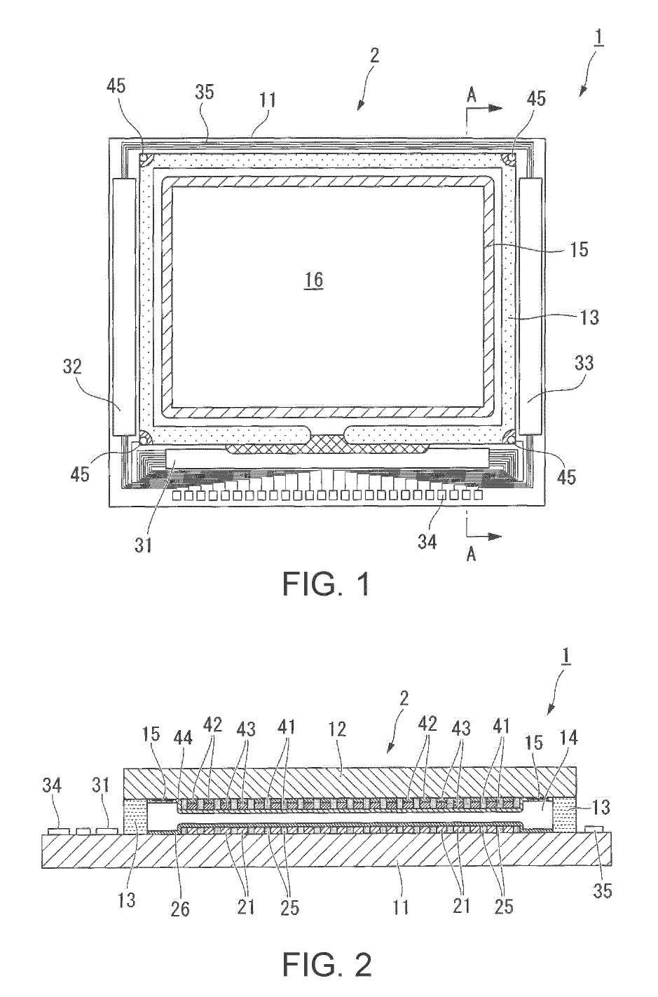

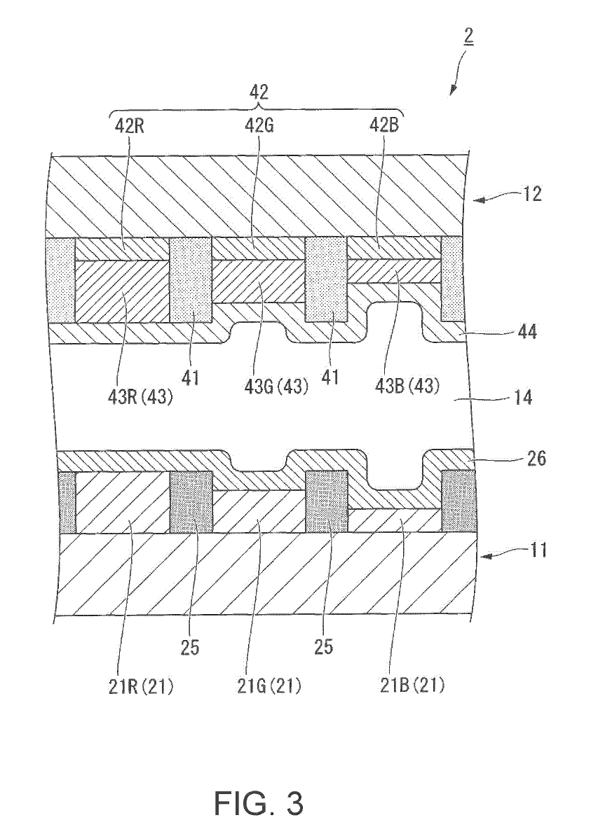

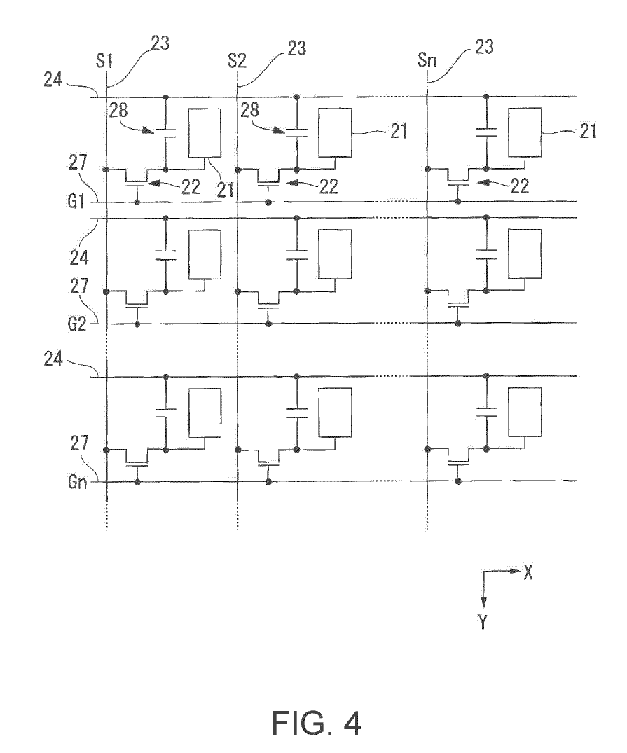

Hereinafter, a description will be given of an embodiment of an electro-optical device and a method for forming an electro-optical device according to the invention with reference to the drawings. FIG. 1 is a plan view of a liquid crystal apparatus. FIG. 2 is a cross sectional view taken along line A-A in FIG. 1, looking in the direction of the appended arrows. FIG. 3 is an enlarged partial view of FIG. 2. FIG. 4 is an equivalent circuit schematic view of the liquid crystal apparatus. It should be noted that in the drawings used for explanation the individual members are shown on different scales in order that each of them shown in the drawings has a recognizable size.

A liquid crystal apparatus (an electro-optical device) 1 of the embodiment is a thin film transistor (TFT) active matrix liquid crystal apparatus using a thin film transistor as a pixel switching element. The liquid crystal apparatus 1 includes a liquid crystal panel 2 and a polarizing plate (not shown) provided on both external faces of the liquid crystal panel 2 as shown in FIGS. 1 to 4.

The liquid crystal panel 2 includes a facing substrate (first substrate) 12, a TFT substrate (second substrate) 11, a seal member 13, and a liquid crystal layer (electro-optical layer) 14 as shown in FIGS. 1 to 3. The facing substrate 12 is disposed opposite the TFT substrate 11. The seal member 13 seals the TFT substrate 11 and the facing substrate 12. The liquid crystal layer 14 is enclosed in a cell gap defined by the TFT substrate 11 and the facing substrate 12. The liquid crystal panel 2, as shown in FIGS. 1 and 2, has a periphery light shielding film 15 formed inside the seal member 13 while the TFT substrate 11 and the facing substrate 12 overlap with each other. The periphery light shielding film 15 defines an image display area 16 in the sealed area. Incidentally the facing substrate 12 is not shown in FIG. 1.

TFT substrate 11 has a rectangular shape when viewed from the top as shown in FIGS. 1 to 3, and is made of translucent material such as glass, quartz and plastic. Formed on the TFT substrate 11 in an area overlapping the image display area 16 are pixel electrodes 21, TFT elements 22, and a plurality of data lines 23 and scanning lines 24, as shown in FIGS. 2 to 4. Formed on an inner surface of the TFT substrate 11 are a partition wall 25 and further an orientation film 26 thereon.

The pixel electrodes 21 are made of translucent conductive material such as indium tin oxide (ITO). The pixel electrodes are formed by dropping and drying pixel electrode forming material liquid 52 (described later) in which ITO fine particles as pixel electrode forming material (electrode forming material) are dispersed. The pixel electrode 21 is provided to each of plural pixel regions which are arranged in a plane. The pixel electrode 21 is opposed to a facing electrode (first electrode) 43 provided to the facing substrate 12 with a liquid crystal layer 14 interposed between the pixel electrode 21 and the facing electrode 43, as shown in FIGS. 2 to 3

The pixel electrodes 21 have the layer thicknesses set depending on wavelength ranges of lights transmitted through colored layers 42R, 42G and 42B of a color filter layer 42 (described later) as shown in FIG. 3. That is, the pixel electrodes 21 mutually have the different layer thicknesses which are layer thicknesses of pixel electrodes 21R, 21G and 21B. The pixel electrodes 21R, 21G and 21B are respectively provided corresponding to the colored layer 42R, 42G and 42B (described later) to transmit the red light, green light and blue light.

The pixel electrode 21R has the layer thickness such that a transmittance for the red light is maximum. The pixel electrode 21G has the layer thickness such that a transmittance for the green light is maximum. The pixel electrode 21B has the layer thickness such that a transmittance for the blue light is maximum. For example, in the embodiment, in a case that the red light wavelength is 630 nm, the green light wavelength is 550 nm, the blue light wavelength is 465 nm, and a refractive index of ITO constituting the pixel electrodes 21 is 1.8, the layer thicknesses of the pixel electrodes 21R, 21G and 21B are respectively 175 nm, 154 nm and 129 nm.

Setting the layer thicknesses of the pixel electrodes 21R, 21G and 21B as described above leads to the followings. For example, in the pixel electrodes 21R, consider the red light component which is light incident on the pixel electrode 21R and transmitted through the colored layer 42R. Light travels in the pixel electrode 21R from an incident plane of the pixel electrode 21R to an emitting plane. This light is a transmitted light. Light is reflected on the emitting plane and the incident plane, and travels to the emitting plane. This light is reflection light. The transmitted light and the reflection light mutually intensify. Therefore, intensity ratio between the incident light and the emitted light of the pixel electrode 21R for the red light component, that is, light loss is reduced.

The TFT element 22 is constituted by an n-type transistor, for example, and disposed at each of intersections of the data lines 23 and the scanning lines 24. The TFT element is formed by forming partially on an upper surface of the TFT substrate 11 an amorphous polysilicon film or a polysilicon film made by crystallizing the amorphous polysilicon film, and by performing partially implantation and activation of impurities thereto. The TFT element 22 has a source electrode coupled to the data line 23, a gate electrode coupled to the scanning line 24, and a drain electrode coupled to the pixel electrode 21. Coupled between the pixel electrode 21 and a capacity line 27 is a retentive capacity 28 in order to prevent an image signal written in the pixel electrode 21 from leaking.

The TFT substrate 11 has the partition wall 25 formed on the inner surface thereof to partition the surface of the TFT substrate 11 so as to overlap the TFT element 22, data line 23 and scanning line 24, as well as surround the pixel electrode 21 when viewed from the top, as shown in FIGS. 2 to 3.

The partition wall 25 is formed to partition the surface of the TFT substrate 11 so as to overlap the TFT element 22, data line 23 and scanning line 24 as well as surround the pixel electrode 21 when viewed from the top. The partition wall 25 is made of organic material such as acrylic, polyamide and epoxy, and has insulation properties.

The data line 23 is a wiring of metal such as aluminum as shown in FIG. 4, and formed to extend in a Y direction indicated in FIG. 4. The scanning line 24 is formed to extend in an X direction indicated in FIG. 4 similar to the data line 23. These data lined 23 and scanning lines 24 partition the pixels.

The TFT substrate 11 has a jutting area jutting out of the facing substrate 12 at one side thereof (base side in FIG. 1), as shown in FIG. 1.

Provided on the TFT substrate 11 are a data line driving circuit 31 along the side described above, and scanning line driving circuits 32 and 33 along two sides adjacent to the relevant side. On the jutting area of the TFT substrate 11 provided are a terminal portion 34 as a terminal group of the data line driving circuit 31 and the scanning line driving circuits 32 and 33. The data line driving circuit 31, scanning line driving circuits 32 and 33, and terminal portion 34 are appropriately coupled with one another by wirings 35.

The data line driving circuit 31 has a structure to supply the data lines 23 with image signals S1, S2, . . . as shown in FIG. 4 base on the signal supplied thereto. It should be noted that the image signal to be written in the data lines 23 by the data line driving circuit 31 may be supplied in a sequence of the lines or for every group of the data lines 23 adjacent to each other.

The scanning line driving circuits 32 and 33 have a structure to supply the scanning lines 24 with scan signals G1, G2, . . . as shown in FIG. 4 base on the signal supplied thereto at a predetermined timing in a pulsed manner. The scan signal to be sent to the scanning line 24 by the scanning line driving circuits 32 and 33 is supplied in a sequence of the lines.

The orientation film 26 is provided on the pixel electrodes 21 and the partition wall 25, and formed of a film of translucent organic material such as a polyamide film which is subjected to a predetermined orientation process such as rubbing process.

The facing substrate 12 has a rectangular shape when viewed from the top as shown in FIGS. 1 and 2 similar to the TFT substrate 11, and is made of translucent material such as glass, quartz and plastic. Formed on a surface of the facing substrate 12 on a liquid crystal layer 14 side are a partition wall 41, a color filter layer 42 and facing electrodes 43, and further an orientation film 44 thereon.

The partition wall 41 is formed to partition the surface of the facing substrate 12 so as to overlap the TFT element 22, data line 23 and scanning line 24 as well as surround the facing electrodes when viewed from the top 43 similar to the partition wall 25. The partition wall 41 is made of photosensitive organic material such as acrylic, polyamide and epoxy which have photosensitivity and in which carbon particles are dispersed thereby to have conductive properties. An electrical conductivity of the partition wall 41 is equal to that of the facing electrode 43. As a result, sufficiently is ensured electrical continuity between facing electrodes 43 adjacent to each other with the partition wall 41 therebetween, and electric potentials of the individual facing electrodes 43 can be common. Here, the partition wall 41 has the conductive properties by dispersing the carbon particles in photosensitive resin material, however other conductive fine particles may be dispersed, not limited to the carbon particles.

The color filter layer 42 is formed on the facing substrate 12 and includes the colored layer 42R to transmit the red light, the colored layer 42G to transmit the green light and the colored layer 42B to transmit the blue light. The colored layers 42R, 42G and 42B are made of photosensitive resin material, for example, and formed in areas partitioned by the partition wall 41. Here, center wavelengths of the transmitted lights of the colored layers 42R, 42G and 42B are respectively 630 nm, 550 nm and 465 nm.

The facing electrodes 43 are made of translucent conductive material such as ITO similar to the pixel electrode 21. The facing electrode 43 is provided correspondingly to each of the pixel regions similar to the pixel electrode 21. The pixel electrodes 43 have the layer thicknesses set depending on wavelength ranges of lights transmitted through the colored layers 42R, 42G and 42B of the color filter layer 42. That is, the pixel electrodes 43 mutually have the different layer thicknesses which are layer thicknesses of facing electrodes 43R, 43G and 43B respectively provided corresponding to the colored layers 42R, 42G and 42B. The facing electrodes 43R, 43G and 43B have respectively the layer thicknesses such that the transmittances for the red, green and blue lights are maximum. For example, in the embodiment, the layer thicknesses of the facing electrodes 43R, 43G and 43B are respectively 175 nm, 154 nm and 129 nm.

Therefore, for example, in the facing electrode 43R, consider the red light component which is light incident on the facing electrode 43R and transmitted through the colored layer 42R. Light travels in the facing electrode 43R from an incident plane of the facing electrode 43R to an emitting plane. This light is a transmitted light. Light is reflected on the emitting plane and the incident plane and travels to the emitting plane. This light is reflection light. The transmitted light and the reflection light mutually intensify.

Between the facing electrodes 43 the electrical continuity is achieved since the partition wall 41 has the conductive properties. Therefore, electric potential of each of the facing electrodes 43 is equal to each other, thereby the electric potentials of all the facing electrodes 43 can be controlled by only applying a voltage to one of the facing electrodes 43.

The orientation film 44 is formed of a translucent organic film such as a polyamide film which is subjected to a predetermined orientation process such as rubbing process similar to the orientation film 26. A rubbing direction of the orientation film 44 is substantially the same as a rubbing direction of the orientation film 26. The facing substrate 12 has continuity members 45 between substrates provided on the corners thereof ensuring the electrical continuity between the TFT substrate 11 and the facing substrate 12.

The liquid crystal layer 14 is in a predetermined orientation state between the orientation films 26 and 44 as shown in FIGS. 1 to 3. The liquid crystal layer 14 can adopt the liquid crystal modes including a twisted nematic (TN) mode, vertical aligned nematic (VAN) mode, super twisted nematic (STN) mode, electrically controlled birefringence (ECB) mode, and optical compensated bend (OCB) mode.

### Method for Manufacturing Liquid Crystal Apparatus

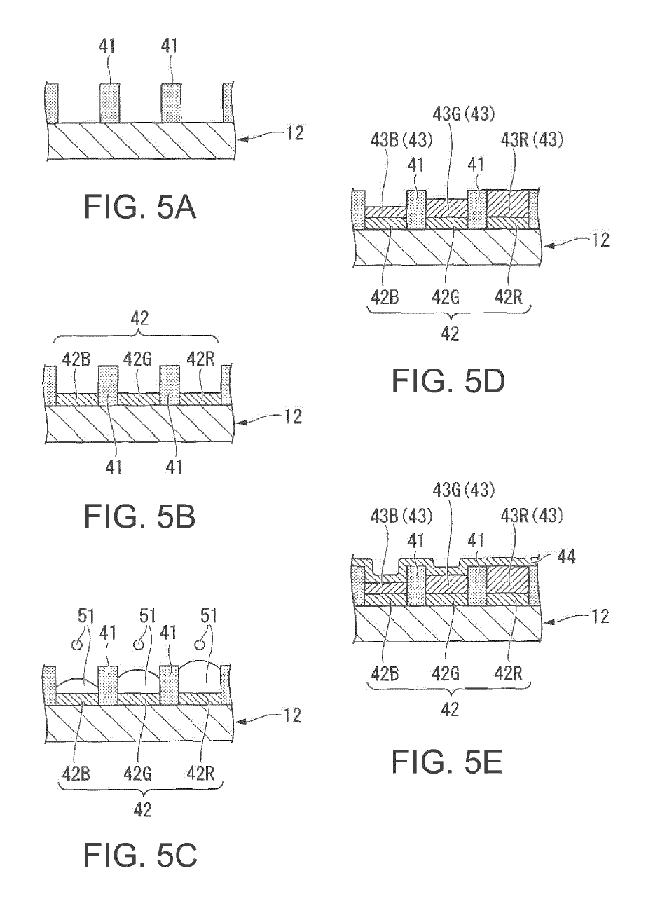

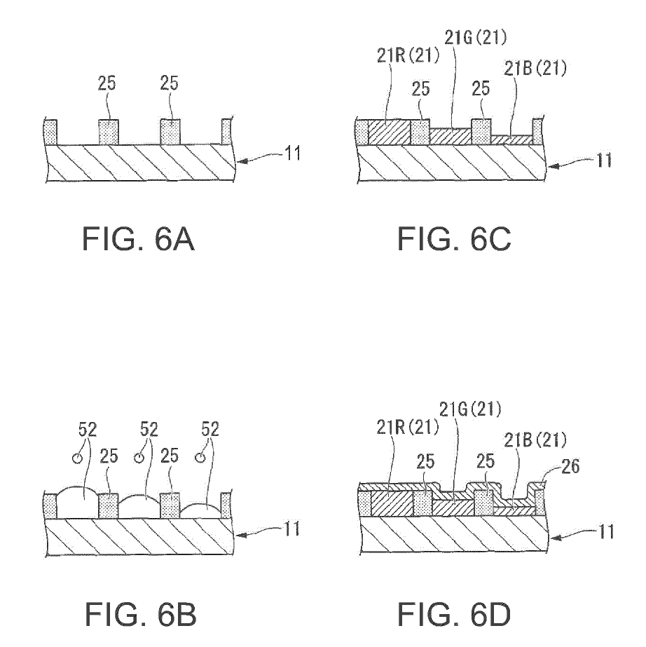

Next, a method for manufacturing a liquid crystal apparatus having the structure above will be described with reference to FIGS. 5A to 5E and 6A to 6D. FIGS. 5A to 5E and 6A to 6D are cross sectional views showing manufacturing steps of the liquid crystal apparatus. It should be noted that in the following description a manufacturing step of the liquid crystal panel is mainly explained because the method has features.

The manufacturing step of the liquid crystal panel according to the embodiment has a facing substrate forming step and a TFT substrate forming step.

First, the facing substrate forming step is performed. The facing substrate forming step includes a partition wall forming step, a color filter layer forming step and a facing electrode forming step.

Firstly, the partition wall forming step is performed. First, a partition wall layer is formed as follows. Applied on all over the surface of the facing substrate 12 made of translucent material such as glass is conductive photosensitive organic material including the carbon particles by use of a spin coat method or the like, and then dried. In the partition wall layer, openings are formed on the pixel regions where the color filter layer 42 and the facing electrodes 43 are formed by photolithographic technique using a mask (not shown). In this way the partition wall 41 is formed on the inner surface of the facing substrate 12 (FIG. 5A).

Then, the inner surface of the partition wall 41 is subjected to a lyophilic process so as to have lyophilicity to facing electrode forming material liquid (first electrode forming material liquid) 51, described later. The lyophilic process is conducted by to the inner surface of the partition wall 41, performing plasma treatment and applying a lyophilic surface preparation agent such as a silane coupling agent, for example.

Next, the color filter layer forming step is performed. First, the colored layer is formed a follows. On all over the surface of the facing substrate 12 where the partition wall 41 is formed, organic material is applied which is colored so as to transmit the red light by use of the spin coat method or the like, and then dried. The colored layer 42R to transmit the red light is formed in the opening area of the partition wall 41 by the photolithographic technique using a mask (not shown). In the same manner as the method for forming the colored layer 42R, formed are the colored layer 42G to transmit the green light and the colored layer 42B to transmit the blue light. In this way, the colored layers 42R, 42G and 42B are formed on the inner surface of the facing substrate 12 in the opening areas of the partition wall 41 to form the color filter layer 42 (FIG. 5B).

Next, the facing electrode forming step is performed. In this step, liquid droplets of the facing electrode forming material liquid 51 are disposed on the color filter layer 42 in the opening areas of the partition wall 41 formed on the inner surface of the facing substrate 12 by a liquid droplet discharging method (FIG. 5C). The facing electrode forming material liquid 51 is made by dispersing the ITO fine particles in dispersion medium and forms the facing electrode 43.

The surface of the ITO fine particles may be coated with organic matter or the like in order to improve dispersibility in the dispersion medium. A diameter of the ITO fine particles is preferably equal to or more than 1 nm and equal to or less than 100 nm. This is because nozzle clogging may occur if the particle diameter is more than 100 nm. Further, if the particle diameter is less than 1 nm, volume ratio of the coating agent to the ITO fine particles is large thereby to excessively increase ratio of the organic matter in the film obtained.

The dispersion medium is not particularly limited so long as it can include the ITO fine particles dispersed therein and is not aggregated. Examples of the dispersion medium are water; alcohol such as methanol, ethanol, propanol, and butanol; hydrocarbon compound such as n-heptane, n-octane, decane, dodecane, tetradecane, toluene, xylene, cymene, durene, indene, dipentene, tetrahydronaphthalene, decahydronaphthalene and cyclohexylbenzene; ether compound such as ethyleneglycoldimethylether, ethyleneglycoldiethylether, ethyleneglycolmethylethylether, diethyleneglycoldimethylether, diethyleneglycoldiethylether, diethyleneglycolmethylethylether, 1,2-dimethoxyethane, bis(2-methoxyethyl)ether, and p-dioxane; and polar compound such as propylenecarbonate, γ-butyrolactone, N-methyl-2-pyrrolidone, dimethylformamide, dimethylsulfoxide and cyclohexanone. Among these preferable are water, alcohol, hydrocarbon compound and ether compound in view of the dispersibility of the fine particles and the stability of dispersion liquid, and the ease of application to the liquid droplet discharging method. Water and hydrocarbon compound are more preferable.

It is preferable that surface tension of the facing electrode forming material liquid 51 is in a range equal to or more than 0.02 N/m and equal to or less than 0.07 N/m. When the liquid droplet is discharged by the liquid droplet discharging method, in a case of the surface tension less than 0.02 N/m, the wettability of ink composition with respect to a nozzle surface is increased and a curved flight is likely to occur. In a case of the surface tension more than 0.07 N/m, since a meniscus shape is not stable at the tip of a nozzle, the amount and timing of discharge are difficult to control. The above dispersion liquid may be added with a surface tension adjusting agent of fluorine series, silicon series, nonion series and others in minute amounts in such a range that a contact angle with the substrate is not excessively lowered in order to adjust the surface tension. The surface tension adjusting agent of nonion series can control wettability of the liquid for the substrate, improve leveling of the film, and help suppressing generation of minute irregularities on the film, and the like. The surface tension adjusting agent may include organic compound such as alcohol, ether, ester and ketone, if required.

The facing electrode forming material liquid 51 is added with a dispersion stabilizer to prevent the ITO fine particles from being brought into contact with other and aggregated. The dispersion stabilizer uses amine compound such as alkylamine. The dispersion stabilizer needs to withdraw from surfaces of metal fine particles and finally be able to evaporate with the dispersion medium. The dispersion stabilizer preferably has a boiling point in a range not exceeding 300 degrees C. at least and generally in a range equal to or less than 250 degrees C. Alkylamine used is one which has alkyl group selected in C8 to C18 and amino group located at the end of alkyl chain, for example. The alkylamine group of C8 to C18 has thermal stability, vapor pressure not so high in a room temperature, and rate of content easily maintained and controlled in a desired range when stored in a room temperature. Therefore the alkylamine group is preferably used in terms of handling ability thereof.

A density of the facing electrode forming material liquid 51 is preferably equal to or more than 1 mPa·s and equal to or less than 50 mPa·s. The reason is as follows. When liquid material is discharged as droplets by the liquid droplet discharging method, in a case of the density less than 1 mPa·s, the periphery of the nozzle is likely to be contaminated by the ink flowing out. In a case of the density more than 50 mPa·s, clogging of the nozzle hole more frequently occurs and the droplet is difficult to smoothly discharge.

Examples of a discharge technique of the liquid droplet discharging method include an electrification controlling method, a pressure vibration method, an electromechanical conversion method, an electro-thermal conversion method, and an electrostatic absorption method. The electrification control method is one in which an electric charge is imparted to the material by a charging electrode, and the material is discharged from the nozzle while an emission direction of the material is controlled by a deflection electrode. The pressure vibration method is one in which a very high pressure of about 30 kg/cm2 is applied to the material so as to be discharged from the tip of the nozzle. If no control voltage is applied, the material is discharged from the nozzle in a straight line. If the control voltage is applied, electrostatic repulsion is engendered between the various portions of the material, so that the material is scattered and is not discharged from the nozzle. The electromechanical conversion method is one which takes advantage of the characteristic that a piezo element (a piezo-electric element) is deformed when subjected to a pulse type electrical signal. The material is discharged as follows. A pressure is applied to a space in which the material is stored via a flexible member by use of such a deformation of the piezo element. The material is pushed out from this space to be discharged from the nozzle. The electro-thermal conversion method is one in which the material is abruptly vaporized by a heater provided within a space in which the material is stored so that bubbles are generated therein. Then the material within this space is discharged therefrom due to the pressure of the bubbles. The electrostatic absorption method is one in which a very small pressure is applied to the space in which the material is stored, so that a meniscus is created upon the material at the nozzle. Then, in this state, the material is discharged by being subjected to static electrical attraction. In addition, it is also possible to apply various techniques such as a method which takes advantage of the change of viscosity of liquid due to an electric field, or a method in which the liquid is caused to be discharged by an electric spark discharge, or the like. These liquid droplet discharging methods do not waste any materials, rather, they have the advantageous feature that they can accurately dispose an appropriate and desired amount of liquid material in the desired position. It should be noted that the amount of the facing electrode forming material liquid 51 in a single drop which is discharged by these liquid droplet discharging methods is, for example, from 1 ng to 300 ng.

The droplets of the facing electrode forming material liquid 51 are disposed on the colored layers 42R, 42G and 42B constituting the color filter layer 42 by the liquid droplet discharging method. An amount of the droplets are decreased in the order of the colored layers 42R, 42G and 42B if concentrations of ITO in the facing electrode forming material liquid 51 disposed are identical.

The disposed facing electrode forming material liquid 51 is subjected to a heat treatment to evaporate a solvent inside thereof and to burn the ITO fine particles. By the heat treatment, the facing electrodes 43R, 43G and 43B are formed (FIG. 5D). In this way the layer thicknesses of the facing electrodes 43R, 43G and 43B are determined by varying the applied amount of the facing electrode forming material liquid 51. Therefore, the facing electrodes 43R, 43G and 43B can be easily formed to have the different layer thicknesses with each other.

On this occasion, the droplets of the facing electrode forming material liquid 51 are disposed selectively on the colored layers 42R, 42G and 42B by use of the liquid droplet discharging method. Therefore, the facing electrode forming material liquid 51 is saved from being wasted. The partition wall 41 has the conductive properties so that the electrical continuity is established between the facing electrodes 43R, 43G and 43B with partition wall 41 therebetween formed on the colored layers 42R, 42G and 42B respectively.

Subsequently, formed on the partition wall 41 and the facing electrodes 43R, 43G and 43B is an orientation film forming material layer made of the organic material such as polyamide. The layer is subject to the rubbing process to form the orientation film 44 (FIG. 5E). In this way, the facing substrate 12 is formed.

Next, the TFT substrate forming step is performed. The TFT substrate forming step includes a partition wall forming step and a pixel electrode forming step.

First, formed on the TFT substrate 11 made of translucent material such as glass are the TFT element, a plurality of data lines 23 and scanning lines 24, and the like by known method.

Next, the partition wall forming step is performed. The step is as follows. Similar to the partition wall forming step in the facing substrate forming step described above, the photosensitive organic material is applied on all over the TFT substrate 11 by the spin coat method or the like, and dried to form the partition wall layer. In the partition wall layer, openings are formed on the pixel regions where the pixel electrodes 21 are formed byphotolithographic technique using a mask (not shown). In this way, the partition wall 25 is formed on the inner surface of the TFT substrate 11 (FIG. 6A).

Then, in a manner as described above, the inner surface of the partition wall 25 is subjected to the lyophilic process so as to have lyophilicity to the pixel electrode forming material liquid (second electrode forming material liquid) 52, described later.

Next, the pixel electrode forming step is performed. In this step, similar to the facing electrode forming step, the pixel electrode forming material liquid 52 are disposed in the opening areas of the partition wall 25 formed on the inner surface TFT substrate 11 by a liquid droplet discharging method (FIG. 6B). The pixel electrode forming material liquid 52 includes the ITO fine particles dispersed therein and forms pixel electrode 21. An amount of the droplets of pixel electrode forming material liquid 52 disposed on the TFT substrate 11 is decreased in the order of the areas corresponding respectively to the colored layers 42R, 42G and 42B if concentrations of ITO in the pixel electrode forming material liquid 52 disposed are identical.

The pixel electrode forming material liquid 52 is subjected to the heat treatment to form the pixel electrodes 21R, 21G and 21B (FIG. 6C). The partition wall 25 has the insulation properties so that the pixel electrodes 21R, 21G and 21B are not electrically conducted.

Subsequently, formed on the partition wall 25 and the pixel electrodes 21R, 21G and 21B is an orientation film forming material layer made of the organic material such as polyamide. The layer is subject to the rubbing process to form the orientation film 26 (FIG. 6D). A rubbing direction of the orientation film 26 is substantially the same as a rubbing direction of the orientation film 44. In this way the TFT substrate 11 is formed.

Then, the TFT substrate 11 and the facing substrate 12 are sealed with the seal member 13 therebetween. At the same time, the liquid crystal layer 14 is enclosed between the TFT substrate 11 and the facing substrate 12, thereby to form the liquid crystal panel 2. Further, the TFT substrate 11 and the facing substrate 12 are provided with the polarizing plate on the external surfaces thereof to form the liquid crystal apparatus 1.

### Electronic Apparatus

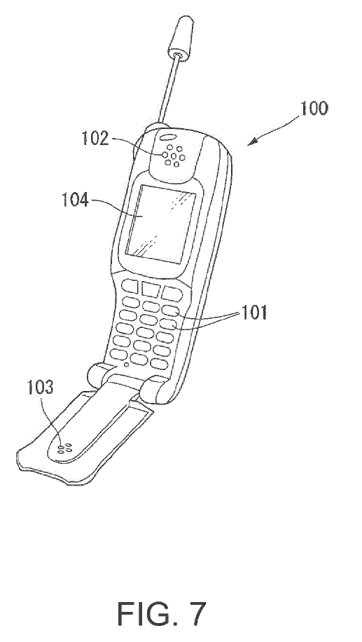

The liquid crystal apparatus 1 having a structure like this is provided to a mobile-phone (electronic apparatus) 100 as shown in FIG. 7, for example. FIG. 7 is a perspective view of the mobile-phone 100. The mobile-phone 100 includes a plurality of operation buttons 101, an earpiece 102, a mouthpiece 103 and a display part 104 constituted by the liquid crystal apparatus 1 of the embodiment.

As described above, according to the liquid crystal apparatus 1 and the method for manufacturing the liquid crystal apparatus of the embodiment, the facing electrodes 43R, 43G and 43B, and the pixel electrodes 21R, 21G and 21B are easily formed to have respectively the different layer thicknesses each of which is determined for every one of colors displayed by the colored layers 42R, 42G and 42B by adjusting the amount of the droplets disposed on the facing electrode forming material liquid 51 and the pixel electrode forming material liquid 52. Therefore, the liquid crystal apparatus 1 can be manufactured, suppressing the luminance variation for every pixel.

Here, since the partition wall 41 has conductive properties, the electrical continuity is established between the facing electrodes 43 with the partition wall 41 therebetween, and the individual facing electrodes 43 have the same electric potential. As a result, the voltage of the facing electrodes 43 can be controlled as a common electrode.

It should be noted that the invention is not limited to the embodiment and various modification can be made within a scope not departing from gist of the invention.

In the above embodiment, both the pixel electrode and the facing electrode are formed by the liquid droplet discharging method, however, either one only may be formed, for example. Also in this way, loss of light can be reduced among lights which are transmitted through either the pixel electrode or the facing electrode formed by the liquid droplet discharging method, with respect to light having a wavelength range of light transmitted through the colored layer provided correspondingly to the relevant electrode.

Further, an insulating layer may be formed between the color filter layer and the facing substrate, or between the color filter layer and the facing electrode for adjusting the layer thickness differences of the colored layers. Specifically, the colored layer may be set to have the layer thickness such that displayed color reproducibility is more improved depending on the wavelength range of the transmitted light for the purpose of improvement of the displayed color reproducibility. As a result, the layer thickness becomes different depending on the wavelength range of the transmitted light. Regarding this matter, the insulating layer made of translucent material is formed adjacent to the colored layer. The combined layer thickness of the colored layer and the insulating layer can be optimized for each colored layer. It is desired that the layer thickness of the insulating layer is determined depending on the wavelength range of light transmitted through the colored layer provided correspondingly thereto similar to the pixel electrode and the facing electrode described above. By this way, can be reduced light loss and the color drift of light transmitted through the colored layer provided correspondingly to the insulating layer.

Similarly, the thickness of either or both of the orientation film on the TFT substrate and the orientation film on the facing substrate may be adjusted depending on the wavelength range of light transmitted through the colored layer provided correspondingly thereto similar to the pixel electrode and the facing electrode described above. By this way, can be reduced light loss and the color drift of light transmitted through the orientation film as described above.

In the embodiment, the partition wall on the facing substrate is made of photosensitive resin material having conductive properties. However, so long as the electrical continuity is ensured between the facing electrodes with the partition wall therebetween, the structure may be in which a layer made of insulation property material and a layer made of conductive property material are laminated to establish the electrical continuity between the facing electrodes by the layer made of the conductive property material. Here, the partition wall may be constructed such that layers made of insulating material and layers made of conductive property material are alternately laminated.

In the embodiment, the partition wall on the facing substrate has conductive properties to establish the electrical continuity between the facing electrodes with the partition wall therebetween. However, the partition wall may be made of insulation property material and have no conductive properties if the electric potential of each facing electrode can be controlled.

The colored layers are formed by use of photolithographic technique in the embodiment, but may be formed by the liquid droplet discharging method similar to the pixel electrode and the facing electrode. At this time, the colored layers are formed in such a manner that droplets of colored layer forming material liquid for forming each colored layer are disposed in the pixel region partitioned by the partition wall on the facing substrate, and dried.

In the embodiment, the color filter layer has the colored layers to transmit the three color lights of red, green and blue, the color display is performed with three colors. However, other three colors may be used for the color display, and further four colors may be used for the color display adding a colored layer to transmit a cyan light therethrough. Moreover, the colored layers to transmit light of at least two colors may be provided, not limiting to the color display.

The description is given of the liquid crystal apparatus as an electro-optical device. However, the electro-optical device may be which performs the color display with light transmitted through the color filter layer, and includes other electro-optical devices such as an organic electroluminescence (EL) device. In a case of using the organic EL device, the color display with the red, green and blue lights can be performed such that light emitting function layer is used as the electro-optical layer which emits a white light by being applied with voltage, and the emitted white light is transmitted through the color filter layer.

Moreover, the description is given of the mobile-phone as the electronic apparatus having the liquid crystal apparatus of the embodiment. However, the liquid crystal apparatus of the embodiment may be applied any other electronic apparatuses which include an electro-optical device such as a liquid crystal apparatus, not limiting to the mobile-phone. The applicable electronic apparatus includes a notebook computer, personal digital assistant (PDA), personal computer, workstation, digital still camera, monitor for automobile, car navigation system, digital video camera, television receiver, video tape recorder of viewfinder or monitor direct-view type, pager, electronic databook, calculator, electronic book, projector, word processor, television-phone, point-of-sale terminal, and apparatus with touch panel.

What is claimed is:

1. A method for manufacturing an electro-optical device having first and second electrodes, an electro-optical layer interposed between the first and second electrodes and a plurality of pixel regions arranged in a plane, and performing display by that light is transmitted through each of colored layers provided correspondingly to each of the pixel regions, the method comprising:
(a) forming a first partition wall partitioning the pixel regions on a first substrate; and
(b) forming first electrodes by applying first electrode forming material liquid to the individual areas partitioned by the first partition wall, wherein in step (b) a layer thickness of each of the first electrodes is set depending on a wavelength range of light transmitted through the colored layer provided correspondingly thereto.

2. The method for manufacturing an electro-optical device according to claim 1, wherein the first partition wall has conductive properties and electrical continuity is established between the first electrodes with the first partition wall therebetween.

3. The method for manufacturing an electro-optical device according to claim 1, wherein in step (b) the first electrode forming material liquid is applied by a liquid droplet discharging method.

4. The method for manufacturing an electro-optical device according to claim 1, further comprising:
(c) forming a second partition wall partitioning a surface of a second substrate correspondingly to the pixel on the second substrate; and
(d) forming second electrodes by applying second electrode forming material liquid to the individual areas partitioned by the second partition wall and drying, wherein
in step (d) a layer thickness of each of the second electrodes is set depending on a wavelength range of light transmitted through the colored layer provided correspondingly thereto.

5. The method for manufacturing an electro-optical device according to claim 4, wherein in step (d) the second electrode forming material liquid is applied by a liquid droplet discharging method.

6. The method for manufacturing an electro-optical device according to claim 1, further comprising:
(e) forming a color filter layer including the colored layers in the individual areas partitioned by the first partition wall before step (b).

7. The method for manufacturing an electro-optical device according to claim 6, wherein step (e) includes,
(f) forming insulating layers each of which is adjacent to the colored layer, wherein
in step (f) a layer thickness of the insulating layer is set depending on a wavelength range of light transmitted through the colored layer provided correspondingly thereto.

8. The method for manufacturing an electro-optical device according to claim 1, wherein
the electro-optical layer constitutes a liquid crystal layer; and
the method further comprises
(g) forming an orientation film on the first electrodes, wherein in step (g) a layer thickness of the orientation film is set depending on a wavelength range of light transmitted through the colored layer provided correspondingly thereto.

9. An electro-optical device, comprising:
first and second electrodes;
an electro-optical layer interposed between the first and second electrodes;
a plurality of pixel regions arranged in a plane;
a plurality of colored layers provided correspondingly to the pixel regions respectively; and
a color filter layer having the colored layers, wherein the device further comprises partition wall formed on a substrate and partitioning a surface of the substrate, and
a layer thickness of each of the first electrodes is set depending on a wavelength range of light transmitted through the each of the colored layer provided correspondingly thereto.

10. The electro-optical device according to claim 9, wherein the partition wall has conductive properties and electrical continuity is established between the first electrodes with the partition wall therebetween.
